(19) United States
(12) Patent Application Publication
(10) Pub. No.: US 2025/0385667 A1
(43) Pub. Date: Dec. 18, 2025

(54) HIGH VOLTAGE SELECTOR

(71) Applicant: eMemory Technology Inc., Hsin-Chu (TW)

(72) Inventors: Wei-Ming KU, Hsinchu County (TW); Chih-Yang HUANG, Hsinchu County (TW); Cheng-Yu CHUNG, Hsinchu County (TW)

(21) Appl. No.: 19/194,057

(22) Filed: Apr. 30, 2025

Related U.S. Application Data
(60) Provisional application No. 63/659,313, filed on Jun. 12, 2024.

(51) Int. Cl. H03K 17/10

(52) U.S. Cl. CPC H03K 17/10

(57) ABSTRACT

A high voltage selector includes a first input terminal to receive a first input voltage, a second input terminal to receive a second input voltage and an output terminal to generate an output voltage. The higher one of the first input voltage and the second input voltage is selected as the output voltage by the high voltage selector. Even if the magnitude of the first input voltage and the magnitude of the second input voltage are close, the output voltage from the high voltage selector will not produce an abnormal voltage drop.

This application claims the benefit of U.S. provisional application Ser. No. 63/659,313, filed Jun. 12, 2024, the subject matters of which is incorporated herein by reference.

### FIELD OF THE INVENTION

The present invention relates to a selector, and more particularly to a high voltage selector.

### BACKGROUND OF THE INVENTION

FIG. 1 is a schematic circuit block diagram of an IC chip. As shown in FIG. 1, the IC chip 100 includes a voltage source 110, a high voltage selector 120 and an internal circuit 130. The voltage source 110 generates an internal supply voltage V_{DD}. Furthermore, the IC chip 100 further includes a power terminal that receives an external supply voltage V_{PP}.

The high voltage selector 120 has two input terminals and an output terminal. The first input terminal of the high voltage selector 120 receives the internal supply voltage V_{DD}. The second input terminal of the high voltage selector 120 is connected to the power terminal to receive the external supply voltage V_{PP}. The output terminal of the high voltage selector 120 is connected to the internal circuit 130.

The user of the IC chip 100 can decide whether to provide the external supply voltage V_{PP} to the IC chip or not. Furthermore, the higher one of the internal supply voltage V_{DD} and the external supply voltage V_{PP} is selected as an operation voltage V_{OP} by the high voltage selector 120 and transmitted to the internal circuit 130. The internal circuit 130 is operated according to the operation voltage V_{OP}.

FIG. 2A is a schematic circuit diagram illustrating the circuitry structure of the conventional high voltage selector 120. FIG. 2B is a schematic timing waveform diagram illustrating the relationship between associated signals of the conventional high voltage selector 120. The first input terminal of the high voltage selector 120 receives the internal supply voltage V_{DD}. The second input terminal of the high voltage selector 120 is connected to the power terminal to receive the external supply voltage V_{PP}. The output terminal of the high voltage selector 120 generates the operation voltage V_{OP}.

The high voltage selector 120 includes two switching transistors M₁ and M₂. For example, the switching transistors M₁ and M₂ are P-type transistors. The source terminal of the switching transistor M1 is connected to the first input terminal to receive the internal supply voltage V_{DD}. The gate terminal of the switching transistor M₁ is connected to the second input terminal to receive the external supply voltage V_{PP}. The drain terminal of the switching transistor M₁ is connected to the node z. The source terminal of the switching transistor M₂ is connected to the second input terminal to receive the external supply voltage V_{PP}. The gate terminal of the switching transistor M₂ is connected to the first input terminal to receive the internal supply voltage V_{DD}. The drain terminal of the switching transistor M is connected to the node z. Furthermore, the node z is the output terminal of the high voltage selector 120, and the voltage at the node z is the operation voltage V_{OP}.

Please refer to FIG. 2B. According to the relationship between the internal supply voltage V_{DD} and the external supply voltage V_{PP}, the operations of the high voltage selector 120 can be understood. In FIG. 2B, the voltage signal fixed at 3.3 V and indicated by the dotted line is the internal supply voltage V_{DD}. The voltage signal that rises from 0 V to 6.5 V and then drops from 6.5 V to 0 V and indicated by the dashed line is the external supply voltage V_{PP}. The voltage signal indicated by the solid line is the operation voltage V_{OP}. For example, the two switching transistors M₁ and M₂ have the same threshold voltage V_{THP}, and the threshold voltage V_{THP} is −0.8 V.

Before the time point t₁, the internal supply voltage V_{DD} is 3.3 V and the external supply voltage V_{PP} is 0 V. Meanwhile, the gate-source voltage V_{GS2} of the switching transistor M₂ is 3.3 V. Since the gate-source voltage V_{GS2} (3.3 V) is greater than the threshold voltage V_{THP} (−0.8 V), the switching transistor M₂ is turned off. In addition, the gate-source voltage V_{GS1} of the switching transistor M₁ is −3.3 V. Since this gate-source voltage V_{GS1} (−3.3 V) is less than the threshold voltage V_{THP} (−0.8 V), the switching transistor M₁ is turned on. Under this circumstance, the internal supply voltage V_{DD} is transmitted to the node z through the switching transistor M₁, and the operation voltage V_{OP} is equal to the internal supply voltage V_{DD}.

In the time period between the time point t₁ and the time point t₂, the external supply voltage V_{PP} rises and gradually approaches the internal supply voltage V_{DD}. During this time period, since the gate-source voltage V_{GS2} is still positive and greater than the threshold voltage V_{THP} (−0.8 V), the switching transistor M₂ is turned off. In addition, the gate-source voltage V_{GS1} of the switching transistor M₁ gradually increases. Since the gate-source voltage V_{GS1} is still less than the threshold voltage V_{THP} (−0.8 V), the switching transistor M₁ is turned on. Under this circumstance, the internal supply voltage V_{DD} is transmitted to the node z through the switching transistor M₁, and the operation voltage V_{OP} is equal to the internal supply voltage V_{DD}.

In the time period between the time point t₂ and the time point t₃, the external supply voltage V_{PP} rises and approaches the internal supply voltage V_{DD}. During this time period, the gate-source voltage V_{GS1} of the switching transistor M1 is greater than the threshold voltage V_{THP} (−0.8 V), the switching transistor M1 is turned off. A junction diode between source-to-body of the switching transistor M1 is forward biased, and the operation voltage V_{OP} is equal to the internal supply voltage V_{DD} plus a voltage drop. The voltage drop is due to the forward bias of the junction diode. Under this circumstance, the operation voltage V_{OP} will produce a voltage drop, and the voltage drop is approximately equal to the threshold voltage V_{THP} (−0.8 V). Consequently, the operation voltage V_{OP} drops to 2.5 V (i.e., 3.3 V−0.8 V=2.5 V) and then rises as the external supply voltage V_{PP} rises.

In the time period between the time point t₃ and the time point t₄, the external supply voltage V_{PP} is greater than the internal supply voltage V_{DD}. During this time period, the switching transistor M₂ is turned on, and the switching transistor M₁ is turned off. The external supply voltage V_{PP} is transmitted to the node z through the switching transistor M_{2.} The operation voltage V_{OP} is equal to the external supply voltage V_{PP}.

Similarly, in the time period between the time point t₄ and the time point t₅, the external supply voltage V_{PP} decreases and approaches the internal supply voltage V_{DD}. During this time period, the operation voltage V_{OP} will produce a voltage drop, and the voltage drop is approximately equal to the threshold voltage V_{THP} (−0.8 V). Consequently, the operation voltage V_{OP} decreases as the external supply voltage VPP decreases, and the operation voltage V_{OP} decreases to 2.5 V (i.e., 3.3 V−0.8 V=2.5 V).

In the time period between the time point t₅ and the time point t₆, the internal supply voltage V_{DD} is greater than the external supply voltage V_{PP}. During this time period, the switching transistor M₂ is turned off, and the switching transistor M₁ is turned on. The internal supply voltage V_{DD} is transmitted to the node z through the switching transistor M₁. The operation voltage V_{OP} is equal to the internal supply voltage V_{DD}.

As mentioned above, if the difference between the internal supply voltage V_{DD} and the external supply voltage V_{PP} is sufficiently large, the higher one of the internal supply voltage V_{DD} and the external supply voltage V_{PP} is selected as the operation voltage V_{OP} by the high voltage selector 120. However, if the magnitude of the internal supply voltage V_{DD} and the magnitude of the external supply voltage V_{PP} are close, the high voltage selector 120 cannot select the higher voltage between the internal supply voltage V_{DD} and the external supply voltage V_{PP} as the operation voltage V_{OP}. Under this circumstance, the operation voltage V_{OP} will produce an abnormal voltage drop.

### SUMMARY OF THE INVENTION

An embodiment of the present invention provides a high voltage selector. A first input terminal of the high voltage selector receives a first input voltage. A second input terminal of the high voltage selector receives a second input voltage. An output terminal of the high voltage selector circuit generates an output voltage. The high voltage selector includes a detecting stage, a clamping stage and a selecting stage. The detecting stage receives the first input voltage, the second input voltage and an enable signal. If the first input voltage is greater than the second input voltage during an activation period of the enable signal, a detection signal is not activated by the detecting stage. If the first input voltage is less than or equal to the second input voltage during the activation period of the enable signal, the detection signal is activated by the detecting stage. A first terminal of the clamping stage receives the second input voltage. A second terminal of the clamping stage is connected to a first node. A control terminal of the clamping stage is connected to the detecting stage. The selecting stage includes a first switching transistor, a second switching transistor and a third switching transistor. A first terminal of the first switching transistor receives the first input voltage. A second terminal of the first switching transistor is connected to a second node. A control terminal of the first switching transistor is connected to the first node. A first terminal of the second switching transistor is connected to the first node. A second terminal of the second switching transistor is connected to the second node. A control terminal of the second switching transistor is connected to the detecting stage. A first terminal of the third switching transistor is connected to the first node. A second terminal of the third switching transistor receives a supply voltage. A control terminal of the third switching transistor is connected to the detecting stage. A voltage at the second node is the output voltage. When the detection signal is not activated, the clamping stage is turned off, the second switching transistor is turned off, the first switching transistor and the third switching transistor are turned on, and the output voltage is equal to the first input voltage. When the detection signal is activated, the clamping stage is turned on, the first switching transistor and the third switching transistor are turned off, the second switching transistor is turned on, and the output voltage is equal to the second input voltage.

Another embodiment of the invention provides a high voltage selector. The high voltage selector comprises a selecting stage, a detecting stage, and a clamping stage. The selecting stage is configured to receive a first input voltage. The clamping stage connected to the selecting stage is configured to receive a second input voltage. And the detecting stage connected to the selecting stage and the clamping stage is configured to receive the first input voltage and the second input voltage. The detecting stage is configured to control the selecting stage and the clamping stage, by a control signal, according to magnitude relationship between the first input voltage and the second input voltage. When the first input voltage is greater than the second input voltage, the detecting stage turns off the clamping stage and controls the selecting stage to output the first input voltage as an output voltage. When the first input voltage is less than or equal to the second input voltage, the detecting stage turns on the clamping stage to transmit the second input voltage to the selecting stage and controls the selecting stage to output the second input voltage as the output voltage.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a schematic circuit block diagram of an IC chip;

FIG. 2A (prior art) is a schematic circuit diagram illustrating the circuitry structure of a conventional high voltage selector;

FIG. 2B (prior art) is a schematic timing waveform diagram illustrating the relationship between associated signals of the conventional high voltage selector;

FIG. 3A is a schematic circuit diagram illustrating the circuitry structure of a high voltage selector according to a first embodiment of the present invention;

FIG. 3B is a schematic timing waveform diagram illustrating the relationship between associated signals of the high voltage selector according to the first embodiment of the present invention; and

FIG. 4 is a schematic circuit diagram illustrating the circuitry structure of a high voltage selector according to a second embodiment of the present invention.

### DETAILED DESCRIPTION OF PREFERRED EMBODIMENTS

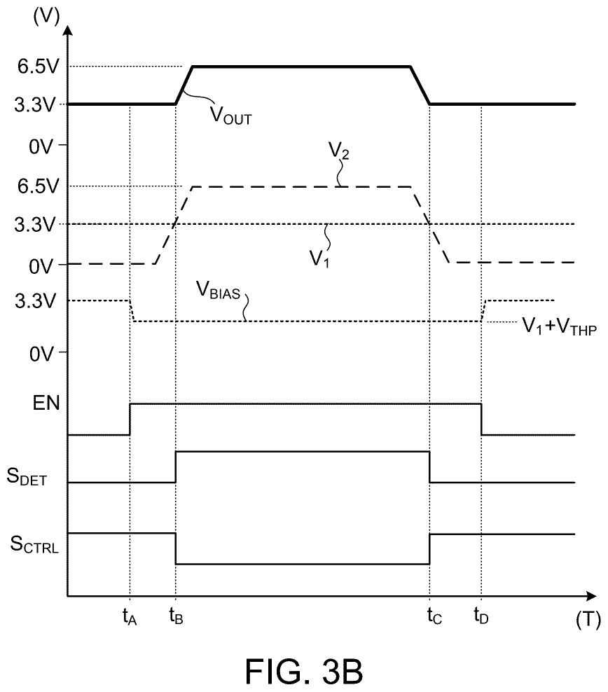

FIG. 3A is a schematic circuit diagram illustrating the circuitry structure of a high voltage selector 300 according to a first embodiment of the present invention. FIG. 3B is a schematic timing waveform diagram illustrating the relationship between associated signals of the high voltage selector 300 according to the first embodiment of the present invention.

A first input terminal of the high voltage selector 300 receives a first input voltage V₁. A second input terminal of the high voltage selector 300 receives a second input voltage V₂. An output terminal of the high voltage selector circuit 300 generates an output voltage V_{OUT}.

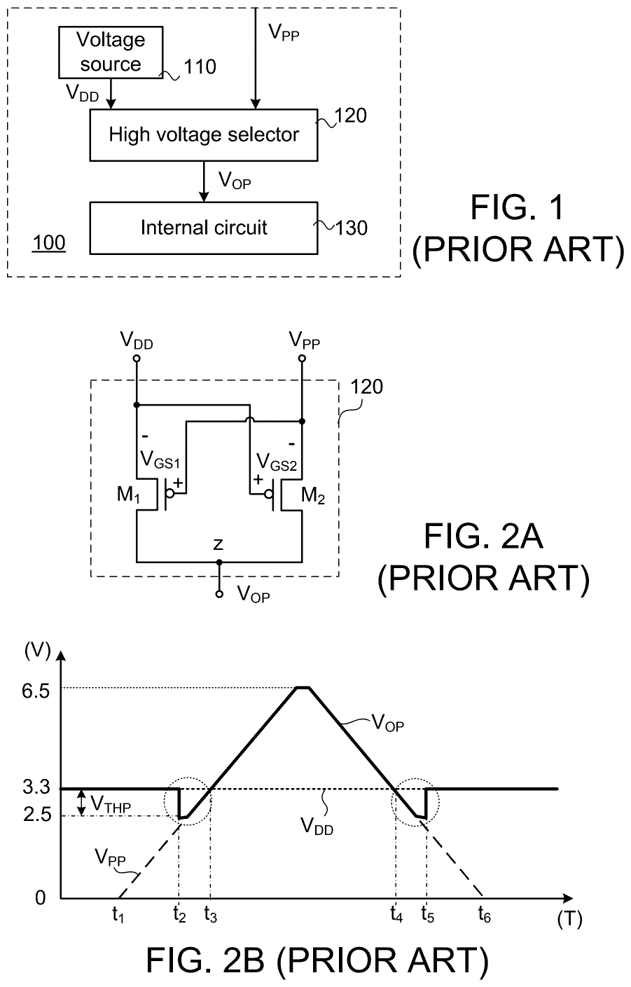

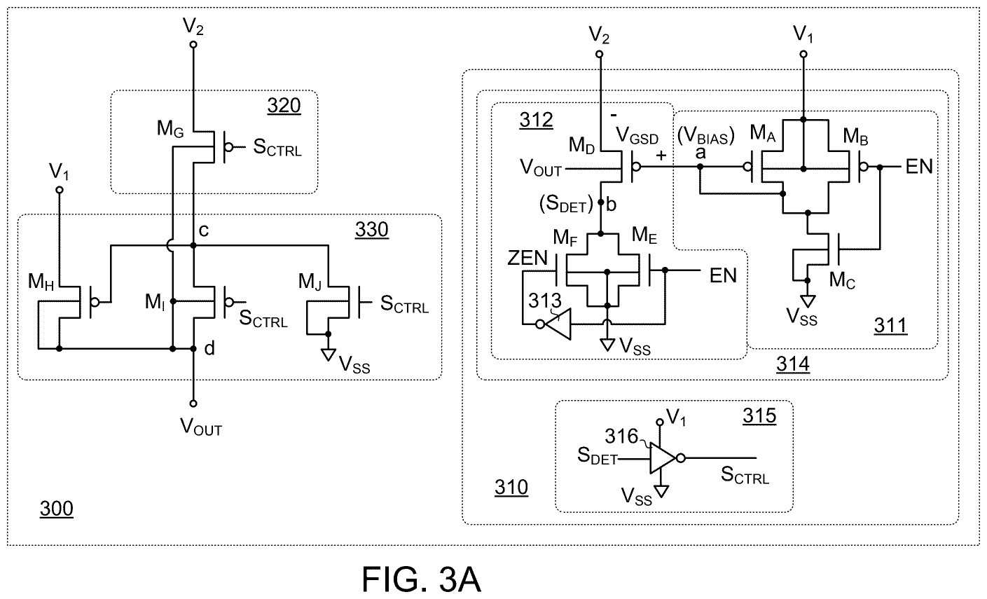

The high voltage selector 300 of the present invention can be applied to the IC chip of FIG. 1 to replace the high voltage selector 120. For example, the first input terminal of the high voltage selector 300 receives the internal supply voltage V_{DD}, and the second input terminal of the high voltage selector 300 receives the external supply voltage V_{PP}. It is noted that the applications of the high voltage selector 300 are not restricted. That is, the high voltage selector 300 can be applied to any other appropriate circuit. By the high voltage selector 300, a higher one of the first input voltage V₁ and the second input voltage V₂ is selected as the output voltage V_{OUT}.

As shown in FIG. 3A, the high voltage selector 300 includes a detecting stage 310, a selecting stage 330, and a clamping stage 320. Furthermore, the detecting stage 310 is operated according to an enable signal EN. For example, when the enable signal EN is activated, the enable signal EN has a logic high level, and the detecting stage 310 can be operated normally. When the enable signal EN is not activated, the enable signal EN has a logic low level, and the detecting stage 310 is disabled. According to the embodiment of the present invention, when the enable signal EN is not activated, the detecting stage 310 is disabled. At this time, the high voltage selector 300 does not select the higher one of the first input voltage V₁ and the second input voltage V₂, but uses the first input voltage V₁ as the output voltage V_{OUT}.

The detecting stage 310 controls the selecting stage 330 and the clamping stage 320, by a control signal S_{CTRL}, according to magnitude relationship between the first input voltage V₁ and the second input voltage V₂. Specifically, the detecting stage 310 includes a detecting circuit 314 and a combinational logic circuit 315. The detecting circuit 314 includes a bias voltage generating circuit 311 and a sensing circuit 312. Furthermore, the detecting stage 310 receives the first input voltage V₁, the second input voltage V₂ and the enable signal EN. The detecting circuit 314 generates a detection signal S_{DET} according to the first input voltage V₁, the second input voltage V₂ and an enable signal EN. The combinational logic circuit 315 is connected to the detecting circuit 314 to receive the detection signal S_{DET}, and converts the detection signal S_{DET} to the control signal S_{CTRL} opposite to the detection signal S_{DET}.

In specific, the bias voltage generating circuit 311 includes transistors M_{A}, M_{B} and M_{C}. The transistors M_{A} and M_{B} are P-type transistors. The transistor M_{C} is an N-type transistor. The source terminal of the transistor MA is connected to the first input terminal of the high voltage selector 300 to receive the first input voltage V₁. The gate terminal of the transistor M_{A} is connected to the node a. The drain terminal of the transistor M_{A} is connected to the node a. That is, transistor M_{A} is a diode-connected transistor. The source terminal of the transistor M_{B} is connected to the source terminal of the transistor M_{A}. The gate terminal of the transistor M_{B} receives the enable signal EN. The drain terminal of the transistor M_{B} is connected to the node a. The drain terminal of the transistor M_{C} is connected to the node a. The gate terminal of the transistor M_{C} receives the enable signal EN. The source terminal of the transistor M_{C} receives a supply voltage V_{SS}. For example, the supply voltage V_{SS} is a ground voltage (0 V). Furthermore, the voltage at the node a is a bias voltage V_{BIAS}.

When the enable signal EN is activated (i.e., having a logic high level), the bias voltage generating circuit 311 is enabled. Meanwhile, the transistor M_{B} is turned off and the transistor M_{C} is turned on. In addition, the transistor M_{A} is regarded as a load. Since the transistor M_{A} is the diode-connected transistor, the bias voltage V_{BIAS} at the node a is approximately equal to the first input voltage V₁ plus the threshold voltage V_{THP} of the transistor M_{A}. That is, V_{BIAS}=V₁+V_{THP}. For example, the threshold voltage V_{THP} is −0.8 V.

The sensing circuit 312 includes transistors M_{D}, M_{E} and M_{F}. The transistor M_{D} is a P-type transistor, and the transistors M_{E} and M_{F} are N-type transistors. The source terminal of the transistor M_{D} is connected to the second input terminal of the high voltage selector 300 to receive the second input voltage V₂. The gate terminal of the transistor M_{D} is connected to the node a to receive the bias voltage V_{BIAS}. The drain terminal of the transistor M_{D} is connected to the node b. The drain terminal of the transistor M_{E} is connected to the node b. The gate terminal of the transistor M_{E} receives the enable signal EN. The source terminal of the transistor M_{E} receives the supply voltage V_{SS}. The drain terminal of the transistor M_{F} is connected to the node b. The gate terminal of the transistor M_{F} receives an inverted enable signal ZEN. The source terminal of the transistor M_{F} receives the supply voltage V_{SS}. The sensing circuit 312 further includes a NOT gate 313. The NOT gate 313 receives the enable signal EN and generates the inverted enable signal ZEN. The voltage at the node b is served as a detection signal S_{DET}. Furthermore, the transistor M_{D} and the transistor M_{A} have the same threshold voltage V_{THP}, and the size of the transistor M_{D} is greater than the size of the transistor M_{E}. In other words, the driving capability of the transistor M_{D} is greater than the driving capability of the transistor M_{E}.

When the enable signal EN is activated, the transistor M_{F} in the sensing circuit 312 is turned off, and the transistor M_{E} is turned on. Furthermore, the gate-source voltage V_{GSD} of the transistor M_{D} is equal to the bias voltage V_{BIAS} minus the second input voltage V₂. That is, V_{GSD}=V_{BIAS}−V₂. Since the bias voltage V_{BIAS}=V₁+V_{THP}, it can be found that V_{GSD}=V₁−V₂+V_{THP}.

If the first input voltage V₁ is greater than the second input voltage V₂, the voltage difference (V₁−V₂) is positive. Therefore, the gate-source voltage V_{GSD} of the transistor M_{D} is greater than the threshold voltage V_{THP}, causing the transistor M_{D} to be turned off and the level of the detection signal S_{DET} to be the supply voltage V_{SS}. That is, the detection signal S_{DET} has a logic low level, indicating that the detection signal S_{DET} is not activated by the detecting stage 310. Whereas, if the first input voltage V₁ is less than or equal to the second input voltage V₂, the voltage difference (V₁−V₂) is 0 or negative. Therefore, the gate-source voltage V_{GSD} of the transistor M_{D} is less than or equal to the threshold voltage V_{THP}, causing the transistor M_{D} to be turned on and the level of the detection signal S_{DET} is the second input voltage V₂. That is, the detection signal S_{DET} has a logic high level, indicating that the detection signal S_{DET} is activated by the detecting stage 310.

The combinational logic circuit 315 includes at least one logic gate to convert the detection signal S_{DET} into at least one control signal. For example, the combinational logic circuit 315 includes a NOT gates 316, and power terminals of the NOT gate 316 receive the first input voltage V₁ and the supply voltage V_{SS}, respectively. The input terminal of the NOT gate 316 receives the detection signal S_{DET}, and the output terminal of the NOT gate 316 generates a control signal S_{CTRL}. It is noted that the combinational logic circuit 315 also can be modified to include three series-connected NOT gates capable of converting the detection signal S_{DET} to the control signal S_{CTRL}.

The first terminal of the clamping stage 320 receives the second input voltage V₂. The second terminal of the clamping stage 320 is connected to the node c. The control terminal of the clamping stage 320 is connected to the detecting stage 310 to receive the control signal S_{CTRL}. The clamping stage 320 includes a switching transistor M_{G}. The switching transistor M_{G} can be a P-type transistor or an N-type transistor. In an embodiment, the switching transistor M_{G} is a P-type transistor. The first terminal of the switching transistor M_{G} is connected to the second input terminal of the high voltage selector 300 to receive the second input voltage V₂. The second terminal of the switching transistor M_{G} is connected to the node c. The control terminal of the switching transistor M_{G} is connected to the detecting stage 310 to receive the control signal S_{CTRL}. For example, the first drain/source terminal of the switching transistor M_{G} is the first terminal of the switching transistor M_{G}. The second drain/source terminal of the switching transistor M_{G} is the second terminal of the switching transistor M_{G}. The gate terminal of the switching transistor M_{G} is the control terminal of the switching transistor M_{G}.

The selecting stage 330 includes switching transistors M_{H}, M_{I} and M_{J}. Similarly, the switching transistors M_{H}, M_{I} and M_{J} are P-type transistors or N-type transistors. For example, the switching transistors M_{H} and M_{I} are P-type transistors, and the switching transistor M_{J} is an N-type transistor. The first terminal of the switching transistor M_{H} is connected to the first input terminal of the high voltage selector 300 to receive the first input voltage V₁. The second terminal of the switching transistor M_{H} is connected to the node d. The control terminal of the switching transistor M_{H} is connected to the node c. The first terminal of the switching transistor M_{I} is connected to the node c. The second terminal of the switching transistor M_{I} is connected to the node d. The control terminal of the switching transistor M_{I} is connected to the detecting stage 310 to receive the control signal S_{CTRL}. The first terminal of the switching transistor M_{J} is connected to the node c. The second terminal of the switching transistor M_{J} receives the supply voltage V_{SS}. The control terminal of the switching transistor M_{J} is connected to the detecting stage 310 to receive the control signal S_{CTRL}. Furthermore, the node d is the output terminal of the high voltage selector 300, and the voltage at the node d is the output voltage V_{OUT}.

The operations of the high voltage selector 300 will be described according to the relationship between the first input voltage V₁ and the second input voltage V₂ shown in FIG. 3B.

The time period between the time point ta and the time point t_{D} is an activation period of the enable signal EN. In the activation period, the enable signal EN is activated, and the detection stage 310 is operated normally.

Before the time point t_{A}, the first input voltage V₁ is 3.3 V, and the second input voltage V₂ is 0 V. The enable signal EN is not activated (i.e., having a logic low level). The detection stage 310 is disabled. Consequently, the detection signal S_{DET} is not activated, the control signal S_{CTRL} has a logic high level, and the detection signal S_{DET} has a logic low level. The switching transistors M_{I} and M_{G} are turned off, and the switching transistors M_{H} and M_{J} are turned on. The output voltage V_{OUT} is thus equal to the first input voltage V₁.

At the time point t_{A}, the enable signal EN is activated (i.e., having a high logic level). Therefore the transistors M_{B} and the transistor M_{F} are turned off and the transistors M_{C} and M_{E} are turned on. The bias voltage V_{BIAS} drops to V₁+V_{THP} (about 2.5 V), that is, smaller than the first input voltage V₁. However, the transistor M_{D} remains turned off because the gate-source voltage V_{GSD} (i.e., V₁−V₂+V_{THP}) of the transistor M_{D} is greater than the threshold voltage V_{THP}. Therefore, the detection signal S_{DET} is not activated, and the clamping stage 320 remains turned off. The output voltage V_{OUT} is thus maintained at the level of the first input voltage V₁.

After the time point t_{A}, the second input voltage V₂ rises. The second input voltage V₂ rises from 0 V and reaches 3.3 V at the time point t_{B}. In the time period between the time point t_{A} and the time point t_{B}, the first input voltage V₁ is greater than the second input voltage V₂. The transistor M_{D} of the detecting stage 310 is turned off because the gate-source voltage V_{GSD} (i.e., V₁−V₂+V_{THP}) of the transistor M_{D} is greater than the threshold voltage V_{THP}. Therefore, the detection signal S_{DET} is not activated, and the output voltage V_{OUT} is thus maintained at the level of the first input voltage V₁.

In the time period between the time point t_{B} and the time point t_{C}, the first input voltage V₁ is 3.3 V, and the second input voltage V₂ further rises from 3.3 V to 6.5 V and then drops to 3.3 V. That is, the enable signal EN is activated and the first input voltage V₁ is less than or equal to the second input voltage V₂. The transistor M_{D} of the detecting stage 310 is turned on because the gate-source voltage V_{GSD} (i.e., V₁−V₂+V_{THP}) of the transistor M_{D} is smaller than or equal to the threshold voltage V_{THP}. Consequently, the detection signal S_{DET} is activated and has the logic high level, and the control signal S_{CTRL} has the logic low level. Furthermore, the clamping stage 320 is turned on. That is, the switching transistor M_{G} is turned on by the control signal S_{CTRL}, and the second input voltage V₂ is transmitted to the node c. In the selecting stage 330, the voltage at the node c is the second input voltage V₂, and the switching transistor M_{H} is turned off. Furthermore, due to the control signal S_{CTRL}, the switching transistor M_{I} is turned on and the switching transistor M_{J} is turned off. The second input voltage V₂ is transmitted from the node c to the node d, and the output voltage V_{OUT} is equal to the second input voltage V₂.

In some embodiments, the size (e.g., width-to-length ratio) and/or driving capability of the switching transistor M_{I} is greater than that of the switching transistor M_{J}, in order to efficiently pull up the output voltage V_{OUT} in case that the switching transistor M_{I} is not fully turned on and the switching transistor M_{J} is not fully turned off. Accordingly, even if the first input voltage V₁ and the second input voltage V₂ are equal at the time point t_{B} and the time point t_{C}, the output voltage V_{OUT} would not produce a voltage drop and would correctly track the higher one of the first input voltage V₁ and the second input voltage V₂.

After the time point t_{C}, the second input voltage V₂ falls to 0 V. Similarly, in the time period between the time point t_{C} and the time point t_{D}, the first input voltage V₁ is greater than the second input voltage V₂. The transistor M_{D} of the detecting stage 310 is turned off, the detection signal S_{DET} is not activated, and the output voltage V_{OUT} is equal to the first input voltage V₁.

After the time point t_{D}, the enable signal EN is set to the logic low level. That is, the enable signal EN is not activated and the first input voltage V₁ is greater than the second input voltage V₂. The transistor M_{D} of the detecting stage 310 is turned off because the gate-source voltage V_{GSD} (i.e., V₁−V₂+V_{THP}) of the transistor M_{D} is greater than the threshold voltage V_{THP}. In the detecting stage 310, the detecting signal S_{DET} is not activated and have the low voltage level, and the control signal S_{CTRL} has the logic high level. Consequently, the clamping stage 320 is turned off and the output voltage V_{OUT} is equal to the first input voltage V₁. In addition, the bias voltage V_{bias} rises to the first input voltage V₁ after the time point t_{D}.

From the above descriptions, the high voltage selector 300 of the first embodiment can effectively select the higher one of the first input voltage V₁ and the second input voltage V₂ as the output voltage V_{OUT}. In case that the magnitude of the first input voltage V₁ and the magnitude of the second input voltage V₂ are close, the output voltage V_{OUT} from the high voltage selector 300 will not produce an abnormal voltage drop.

In the clamping stage 320 of the high voltage selector 300 of the first embodiment, the switching transistor M_{G} is a P-type transistor. It is noted that the type of the switching transistor M_{G} is not restricted. For example, in another embodiment, the switching transistor M_{G} is an N-type transistor. Under this circumstance, the control terminal of the switching transistor M_{G} receives the detection signal S_{DET}, and the purpose of the high voltage selector of the present invention is also achievable.

In order to avoid the generation of a body effect, the body terminals of all transistors in the high voltage selector 300 receive proper voltages. As shown in FIG. 3A, the body terminals of the switching transistors M_{G}, M_{H} and M_{I} are connected to the node d to receive the output voltage V_{OUT}, and the body terminal of the switching transistor M_{J} receives the supply voltage V_{SS}. In addition, the body terminals of the transistors M_{A} and M_{B} receive the first input voltage V₁, the body terminal of the transistor M_{D} is connected to the node d to receive the output voltage V_{OUT}, and the body terminals of the transistors M_{C}, M_{E} and M_{F} receive the supply voltage V_{SS}.

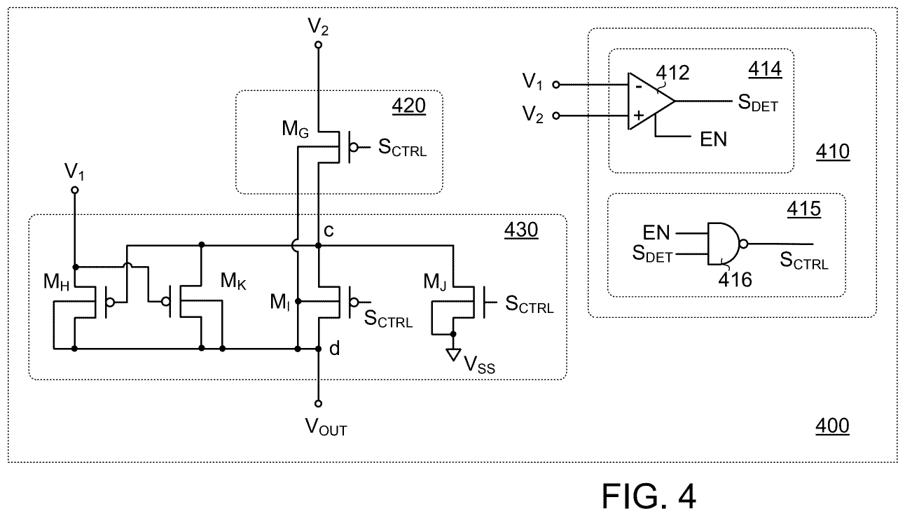

FIG. 4 is a schematic circuit diagram illustrating the circuitry structure of a high voltage selector 400 according to a second embodiment of the present invention. A first input terminal of the high voltage selector 400 receives a first input voltage V₁. A second input terminal of the high voltage selector 400 receives a second input voltage V₂. An output terminal of the high voltage selector circuit 400 generates an output voltage V_{OUT}.

As shown in FIG. 4, the high voltage selector 400 includes a detecting stage 410, a selecting stage 430, and a clamping stage 420. Furthermore, the detecting stage 410 is operated according to an enable signal EN. For example, when the enable signal EN is activated, the enable signal EN has a logic high level, and the detecting stage 410 can be operated normally. When the enable signal EN is not activated, the enable signal EN has a logic low level, and the detecting stage 410 is disabled.

The detecting stage 410 includes a detecting circuit 414 and a combinational logic circuit 415. In the second embodiment, the detecting circuit 414 includes a comparator 412. The inverting input terminal of the comparator 412 is connected to the first input terminal of the high voltage selector 400 to receive the first input voltage V₁. The non-inverting input terminal of the comparator 412 is connected to the second input terminal of the high voltage selector 400 to receive the second input voltage V₂. The output terminal of the comparator 412 generates a detection signal S_{DET}. Furthermore, an enable terminal of the comparator 412 receives the enable signal EN.

For example, if the second input voltage V₂ is less than the first input voltage V₁, the detection signal S_{DET} has a logic low level, indicating that the detection signal S_{DET} is not activated. Whereas, if the second input voltage V₂ is greater than or equal to the first input voltage V₁, the detection signal S_{DET} has the logic high level, indicating that the detection signal S_{DET} is activated.

The combinational logic circuit 415 includes at least one logic gate to convert the detection signal S_{DET} into at least one control signal. For example, the combinational logic circuit 415 includes a NAND gate 416. The first input terminal of the NAND gate 416 receives the enable signal EN. The second input terminal of the NAND gate 416 receives the detection signal S_{DET}. The output terminal of the NAND gate 416 generates a control signal S_{CTRL}.

It is noted that the circuitry structures of the detecting circuit 414 and the combinational logic circuit 415 are not restricted. The combinational logic circuit 415 may be modified according to the logic level of the detection signal S_{DET}. In a variant example, the inverting input terminal of the comparator 412 receives the second input voltage V₂, the non-inverting input terminal of the comparator 412 receives the first input voltage V₁, and the output terminal of the comparator 412 generates the detection signal S_{DET}. In this case, the combination logic 415 may include a NAND gate and a NOT gate. An input terminal of the NOT gate receives the detection signal S_{DET}, and the output terminal of the NOT gate is connected to one input terminal of the NAND gate while the other input terminals of the NAND gate receive the enable signal EN. An output terminal of the NAND gate generates the control signal S_{CTRL}.

The first terminal of the clamping stage 420 receives the second input voltage V₂. The second terminal of the clamping stage 420 is connected to the node c. The control terminal of the clamping stage 420 is connected to the detecting stage 410 to receive the control signal S_{CTRL}. The clamping stage 420 includes a switching transistor M_{G}. The switching transistor M_{G} is a P-type transistor or an N-type transistor. In an embodiment, the switching transistor M_{G} is a P-type transistor. The first terminal of the switching transistor M_{G} is connected to the second input terminal of the high voltage selector 400 to receive the second input voltage V₂. The second terminal of the switching transistor M_{G} is connected to the node c. The control terminal of the switching transistor M_{G} is connected to the detecting stage 410 to receive the control signal S_{CTRL}.

The selecting stage 430 includes switching transistors M_{H}, M_{I}, M_{J} and M_{K}. Similarly, the switching transistors M_{H}, M_{I}, M_{J} and M_{K} are P-type transistors or N-type transistors. For example, the switching transistors M_{H}, M_{I} and M_{K} are P-type transistors, and the switching transistor M_{J} is an N-type transistor. The first terminal of the switching transistor M_{H} is connected to the first input terminal of the high voltage selector 400 to receive the first input voltage V₁. The second terminal of the switching transistor M_{H} is connected to the node d. The control terminal of the switching transistor M_{H} is connected to the node c. The first terminal of the switching transistor M_{K} is connected to the node c. The second terminal of the switching transistor M_{K} is connected to the node d. The control terminal of the switching transistor M_{K} is connected to the first input terminal of the high voltage selector 400 to receive the first input voltage V₁. The first terminal of the switching transistor M_{I} is connected to the node c. The second terminal of the switching transistor M_{I} is connected to the node d. The control terminal of the switching transistor M_{I} is connected to the detecting stage 410 to receive the control signal S_{CTRL}. The first terminal of the switching transistor M_{J} is connected to the node c. The second terminal of the switching transistor M_{J} receives the supply voltage V_{SS}. The control terminal of the switching transistor M_{J} is connected to the detecting stage 410 to receive the control signal S_{CTRL}. Furthermore, the node d is the output terminal of the high voltage selector 400, and the voltage at the node d is the output voltage V_{OUT}.

In case that the magnitude of the first input voltage V₁ and the magnitude of the second input voltage V₂ are close, the switching transistor M_{I} and the switching transistor M_{J} are appropriately controlled, so that the output voltage V_{OUT} from the high voltage selector 400 will not produce an abnormal voltage drop. In some embodiments, the size (e.g., width-to-length ratio) and/or driving capability of the switching transistor M_{K} is greater than that of the switching transistor M_{J} in order to decrease current leakage through the switching transistor M_{J} in case the second input voltage V₂ ramps up slowly and the switching transistor M_{J} cannot be turned off in time.

Furthermore, except for the waveform of the bias voltage V_{BIAS} in FIG. 3B, the waveforms of other signals in FIG. 3B are also applicable to the high voltage selector 400 of the second embodiment. That is, the operations of the high voltage selector 400 of the second embodiment are similar to the operations of the high voltage selector 300 of the first embodiment, and not redundantly described herein.

Similarly, in order to avoid the generation of a body effect, the body terminals of all transistors in the high voltage selector 400 receive proper voltages. For example, as shown in FIG. 4, the body terminals of the switching transistors M_{G}, M_{H}, M_{I} and M_{K} are connected to the node d to receive the output voltage V_{OUT}, and the body terminal of the switching transistor M_{J} receives the supply voltage V_{SS}.

It is noted that the architecture of the high voltage selector is not restricted to the high voltage selector 300 of the first embodiment and the high voltage selector 400 of the second embodiment. For example, a high voltage selector in a third embodiment of the present invention includes the detecting stage 410 of FIG. 4 and the clamping stage 320 and the selecting stage 330 of FIG. 3A. Alternatively, a high voltage selector in a fourth embodiment of the present invention includes the detecting stage 310 of FIG. 3A and the clamping stage 420 and the selecting stage 430 of FIG. 4. As another example, a detecting stage of a high voltage selector in a fifth embodiment includes the detecting circuit 314 of FIG. 3A and the combinational logic circuit 415 of FIG. 4. Alternatively, a detecting stage of a high voltage selector in a sixth embodiment includes the detecting circuit 414 of FIG. 4 and the combinational logic circuit 315 of FIG. 3B.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A high voltage selector, a first input terminal of the high voltage selector receiving a first input voltage, a second input terminal of the high voltage selector receiving a second input voltage, an output terminal of the high voltage selector circuit generating an output voltage, the high voltage selector comprising:
a detecting stage receiving the first input voltage, the second input voltage and an enable signal, wherein if the first input voltage is greater than the second input voltage during an activation period of the enable signal, a detection signal is not activated by the detecting stage, wherein if the first input voltage is less than or equal to the second input voltage during the activation period of the enable signal, the detection signal is activated by the detecting stage;
a clamping stage, wherein a first terminal of the clamping stage receives the second input voltage, a second terminal of the clamping stage is connected to a first node, and a control terminal of the clamping stage is connected to the detecting stage; and
a selecting stage comprising a first switching transistor, a second switching transistor and a third switching transistor, wherein a first terminal of the first switching transistor receives the first input voltage, a second terminal of the first switching transistor is connected to a second node, a control terminal of the first switching transistor is connected to the first node, a first terminal of the second switching transistor is connected to the first node, a second terminal of the second switching transistor is connected to the second node, a control terminal of the second switching transistor is connected to the detecting stage, a first terminal of the third switching transistor is connected to the first node, a second terminal of the third switching transistor receives a supply voltage, a control terminal of the third switching transistor is connected to the detecting stage, and a voltage at the second node is the output voltage,
wherein when the detection signal is not activated, the clamping stage is turned off, the second switching transistor is turned off, the first switching transistor and the third switching transistor are turned on, and the output voltage is equal to the first input voltage,
wherein when the detection signal is activated, the clamping stage is turned on, the first switching transistor and the third switching transistor are turned off, the second switching transistor is turned on, and the output voltage is equal to the second input voltage.

2. The high voltage selector as claimed in claim 1, wherein the selecting stage further includes a fourth switching transistor, wherein a first terminal of the fourth switching transistor is connected to the first node, a second terminal of the fourth switching transistor is connected to the second node, and a control terminal of the fourth switching transistor receives the first input voltage.

3. The high voltage selector as claimed in claim 2, wherein the first switching transistor, the second switching transistor and the fourth switching transistor are P-type transistors, and the third switching transistor is an N-type transistor, wherein a body terminal of the first switching transistor receives the output voltage, a body terminal of the second switching transistor receives the output voltage, a body terminal of the fourth switching transistor receives the output voltage, and a body terminal of the third switching transistor receives the supply voltage.

4. The high voltage selector as claimed in claim 1, wherein the clamping stage comprises a fourth switching transistor, wherein a first terminal of the fourth switching transistor receives the second input voltage, a second terminal of the fourth switching transistor is connected to the first node, and a control terminal of the fourth switching transistor is connected to the detecting stage.

5. The high voltage selector as claimed in claim 4, wherein the first switching transistor, the second switching transistor and the fourth switching transistor are P-type transistors, and the third switching transistor is an N-type transistor, wherein a body terminal of the first switching transistor receives the output voltage, a body terminal of the second switching transistor receives the output voltage, a body terminal of the fourth switching transistor receives the output voltage, and a body terminal of the third switching transistor receives the supply voltage.

6. The high voltage selector as claimed in claim 1, wherein the detecting stage comprises:
a detecting circuit generating the detection signal according to the first input voltage, the second input voltage and an enable signal; and
a combinational logic circuit connected to the detecting circuit to receive the detection signal, and converting the detection signal to a control signal,
wherein when the enable signal is activated and the first input voltage is less than or equal to the second input voltage, the detection signal is activated,
wherein when the enable signal is not activated, the detection signal is not activated.

7. The high voltage selector as claimed in claim 6, wherein the detecting circuit comprises a comparator, wherein an inverting input terminal of the comparator receives the first input voltage, a non-inverting input terminal of the comparator receives the second input voltage, an enable terminal of the comparator receives the enable signal, and an output terminal of the comparator generates the detection signal.

8. The high voltage selector as claimed in claim 6, wherein the combinational logic circuit comprises:
a NAND gate, wherein a first input terminal of the NAND gate receives the enable signal, a second input terminal of the NAND gate receives the detection signal, and an output terminal of the NAND gate generates the control signal;
wherein the control terminal of the clamping stage is connected to the detecting stage to receive the control signal, the control terminal of the second switching transistor is connected to the detecting stage to receive the control signal, and the control terminal of the third switching transistor is connected to the detecting stage to receive the control signal.

9. The high voltage selector as claimed in claim 6, wherein the combinational logic circuit comprises:
a NOT gate, wherein an input terminal of the NOT gate receives the detection signal, and an output terminal of the NOT gate generates the control signal;
wherein the control terminal of the clamping stage is connected to the detecting stage to receive the control signal, the control terminal of the second switching transistor is connected to the detecting stage to receive the control signal, and the control terminal of the third switching transistor is connected to the detecting stage to receive the control signal.

10. The high voltage selector as claimed in claim 6, wherein the detecting circuit comprises a bias voltage generating circuit, and the bias voltage generating circuit comprises:
a first P-type transistor, wherein a source terminal of the first P-type transistor receives the first input voltage, a drain terminal of the first P-type transistor is connected to a third node, a gate terminal of the first P-type transistor is connected to the third node, and a voltage at the third node is a bias voltage;
a second P-type transistor, wherein a source terminal of the second P-type transistor receives the first input voltage, a drain terminal of the second P-type transistor is connected to the third node, and a gate terminal of the second P-type transistor receives the enable signal; and
a first N-type transistor, wherein a drain terminal of the first N-type transistor is connected to the third node, a source terminal of the first N-type transistor receives the supply voltage, and a gate terminal of the first N-type transistor receives the enable signal.

11. The high voltage selector as claimed in claim 10, wherein the detecting circuit comprises a sensing circuit, and the sensing circuit comprises:
a third P-type transistor, wherein a source terminal of the third P-type transistor receives the second input voltage, a drain terminal of the third P-type transistor is connected to a fourth node, and a gate terminal of the third P-type transistor receives the bias voltage;
a second N-type transistor, wherein a drain terminal of the second N-type transistor is connected to the fourth node, a source terminal of the second N-type transistor receives the supply voltage, and a gate terminal of the second N-type transistor receives the enable signal.; and
a third N-type transistor, wherein a drain terminal of the third N-type transistor is connected to the fourth node, a source terminal of the third N-type transistor receives the supply voltage, and a gate terminal of the third N-type transistor receives an inverted enable signal,
wherein a voltage at the fourth node is the detection signal.

12. The high voltage selector as claimed in claim 11, wherein a body terminal of the first P-type transistor receives the first input voltage, a body terminal of the second P-type transistor receives the first input voltage, a body terminal of the third P-type transistor receives the output voltage, a body terminal of the first N-type transistor receives the supply voltage, a body terminal of the second N-type transistor receives the supply voltage, and a body terminal of the third N-type transistor receives the supply voltage.

13. The high voltage selector as claimed in claim 11, wherein the first P-type transistor and the third P-type transistor have a same threshold voltage, and a driving capability of the third P-type transistor is greater than a driving capability of the second N-type transistor.

14. A high voltage selector, comprising:
a selecting stage configured to receive a first input voltage;
a clamping stage configured to receive a second input voltage, and connected to the selecting stage; and
a detecting stage configured to receive the first input voltage and the second input voltage, and connected to the selecting stage and the clamping stage, wherein the detecting stage is configured to control the selecting stage and the clamping stage, by a control signal, according to magnitude relationship between the first input voltage and the second input voltage,
wherein when the first input voltage is greater than the second input voltage, the detecting stage turns off the clamping stage and controls the selecting stage to output the first input voltage as an output voltage,
wherein when the first input voltage is less than or equal to the second input voltage, the detecting stage turns on the clamping stage to transmit the second input voltage to the selecting stage and controls the selecting stage to output the second input voltage as the output voltage.

15. The high voltage selector as claimed in claim 14, wherein the selecting stage comprises:
a first switching transistor, wherein a control terminal of the first switching transistor is connected to a first node, a first terminal of the first switching transistor receives the first input voltage, a second terminal of the first switching transistor is connected to a second node, and the first node is connected to the clamping stage to receive the second input voltage;
a second switching transistor, wherein a first terminal of the second switching transistor is connected to the first node, a second terminal of the second switching transistor is connected to the second node, a control terminal of the second switching transistor is connected to the detecting stage to receive the control signal; and
a third switching transistor, wherein a first terminal of the third switching transistor is connected to the first node, a second terminal of the third switching transistor receives a supply voltage, a control terminal of the third switching transistor is connected to the detecting stage to receive the control signal, and a voltage at the second node is the output voltage.

16. The high voltage selector as claimed in claim 14, wherein the detecting stage comprises:
a detecting circuit configured to generate a detection signal according to the first input voltage, the second input voltage and an enable signal; and
a combinational logic circuit connected to the detecting circuit to receive the detection signal, and configured to generate the control signal according to the detection signal,
wherein when the enable signal is activated and the first input voltage is less than or equal to the second input voltage, the detection signal is activated,
wherein when the enable signal is not activated, the detection signal is not activated.

17. The high voltage selector as claimed in claim 16, wherein the detecting circuit comprises:
a bias voltage generating circuit configured to generate a bias voltage according to the first input voltage and an enable signal; and
a sensing circuit connected to the bias voltage generating circuit, and configured to generate the detection signal according to the second input voltage, the enable signal and the bias voltage,
wherein when the enable signal is activated, the bias voltage is lower than the first input voltage,
wherein when the enable signal is not activated, the bias voltage is equal to the first input voltage.

18. The high voltage selector as claimed in claim 17, wherein the bias voltage generating circuit comprises:
a first transistor, wherein a first terminal of the first transistor receives the first input voltage, a second terminal of the first transistor is connected to a third node, a control terminal of the first transistor is connected to the third node, and a voltage at the third node is the bias voltage;
a second transistor, wherein a first terminal of the second transistor receives the first input voltage, a second terminal of the second transistor is connected to the third node, and a control terminal of the second transistor receives the enable signal; and
a third transistor, wherein a first terminal of the third transistor is connected to the third node, a second terminal of the third transistor receives a supply voltage, and a control terminal of the third transistor receives the enable signal.

19. The high voltage selector as claimed in claim 18, wherein the sensing circuit comprises:
a fourth transistor, wherein a first terminal of the fourth transistor receives the second input voltage, a second terminal of the fourth transistor is connected to a fourth node, and a control terminal of the fourth transistor receives the bias voltage;
a fifth transistor, wherein a first terminal of the fifth transistor is connected to the fourth node, a second terminal of the fifth transistor receives a supply voltage, and a control terminal of the fifth transistor receives the enable signal; and
a sixth transistor, wherein a first terminal of the sixth transistor is connected to the fourth node, a second terminal of the sixth transistor receives the supply voltage, and a control terminal of the sixth transistor receives an inverted enable signal,
wherein a voltage at the fourth node is the detection signal.

20. The high voltage selector as claimed in claim 19, wherein the first transistor and the fourth transistor have a same threshold voltage, and a driving capability of the fourth transistor is greater than a driving capability of the fifth transistor.
